(19) United States
(12) Patent Application Publication
(10) Pub. No.: US 2003/0043555 A1
(43) Pub. Date: Mar. 6, 2003

(54) Electronic component with at least two stacked semiconductor chips and process for producing the electronic component

(76) Inventors: Bernd Goller, Kemnath (DE); Robert-Christian Hagen, Sarching (DE); Gerald Ofner, Bad Abbach (DE); Christian Stumpfl, Schwandorf (DE); Josef Thumbs, Breitenbrunn (DE); Stefan Wein, Regensburg (DE); Holger Worner, Regensburg (DE)

Correspondence Address: LERNER AND GREENBERG, P.A., Post Office Box 2480, Hollywood, FL, 33022-2480, US

(21) Appl. No.: 10/231,883

(22) Filed: Aug. 30, 2002

(30) Foreign Application Priority Data
Aug. 30, 2001 (DE) 101 42 118.4

(51) Int. Cl. H05K 7/02; H05K 7/06; H05K 7/08; H05K 7/10

(52) U.S. Cl. 361/760

(57) ABSTRACT

An electronic component has a carrier substrate to accommodate two semiconductor chips that are connected to each other. The second semiconductor chip rests with two opposite marginal supporting regions on an upper side of the carrier substrate. The first semiconductor chip is disposed at a distance from a frame of the carrier substrate, in a central recess in the latter. A process for the production of the electronic component is further described.

### BACKGROUND OF THE INVENTION

1. Field of the Invention

The invention relates to an electronic component having at least two stacked semiconductor chips and a process for its production.

In many electronic components, a first semiconductor chip module, for example a logic module, and a second semiconductor module, for example a memory module, are needed. In order to save space on a printed circuit board, it is expedient to accommodate both semiconductor chip modules in a common housing with the smallest possible space requirement. Now, a logic module typically has a square base area and a memory module has a rectangular base area, so that when semiconductor chip modules are disposed one above another, as in a known chip-on-chip construction, the bonding contact areas to some extent cover one another. Hitherto, this problem has been solved by the two semiconductor chip modules being disposed beside each other in a common housing, which gives rise to a considerable requirement for space. In an alternative solution, the two semiconductor chip modules are mounted in a lead frame housing, which entails cumbersome and difficult mounting, since the components have to be turned many times and the bonding wires in this case are to some extent exposed. A further principle is also used, in which the semiconductor chip modules are mounted in different housings that are then disposed one above another. However, this is also a complicated and costly process, which in addition leads to a large and high installation height of the electronic component of this type.

Published, Japanese Patent Application JP 08250651-A discloses a semiconductor configuration in which two semiconductor chip modules are disposed one above the other in spaces separated by an intermediate wall. The two semiconductor chip modules are connected to outer contacts via conductor tracks by bonding wires. This known semiconductor configuration takes up a great deal of space and is cumbersome and complicated to produce.

### SUMMARY OF THE INVENTION

It is accordingly an object of the invention to provide an electronic component with at least two stacked semiconductor chips and a process for producing the electronic component which overcome the above-mentioned disadvantages of the prior art devices and methods of this general type, which is constructed simply and can be produced economically and which takes up little space, in order to overcome the disadvantages of the prior art.

With the foregoing and other objects in view there is provided, in accordance with the invention, an electronic component. The electronic component contains semiconductor chips including a first semiconductor chip and a second semiconductor chip, and a carrier substrate accommodating the semiconductor chips and has an upper side and a frame with a central recess. The second semiconductor chip has two opposite marginal supporting regions resting on the upper side of the carrier substrate. The first semiconductor chip is connected to the second semiconductor chip and disposed at a distance from the frame in the central recess of the carrier substrate.

According to the invention, the electronic component has the first semiconductor chip, the second semiconductor chip, and the carrier substrate to accommodate the semiconductor chips.

Provision is made for the second semiconductor chip to rest with two opposite marginal supporting regions on an upper side of the carrier substrate, and for the first semiconductor chip to be connected to the second semiconductor chip and to be disposed at a distance from a frame of the carrier substrate, in a central recess in the latter.

The electronic component according to the invention has the advantage that, because of the semiconductor chips joined to each other, two semiconductor chip modules with different external dimensions can be accommodated in a common housing in a space-saving way. It is therefore possible to stack a rectangular semiconductor chip with a square semiconductor chip and vice versa, the semiconductor chips overlapping only to some extent and both semiconductor chips each having regions which project beyond the overlap. For external dimensions that are different in this way, the prior art does not provide any usable solution.

One embodiment of the invention provides for the first semiconductor chip and the second semiconductor chip in each case to be electrically conductively connected by first and second bonding wires. This embodiment has the advantage of a very compact configuration, which can additionally be produced simply.

In an alternative embodiment of the invention, additional electrical connections between the first semiconductor chip and second semiconductor chip are provided by third bonding wires. These electrical chip-to-chip connections between the first and second semiconductor chip permit compact electronic components. In this case, a large number of electrical connections between the chips and the carrier substrate can be accommodated in an extremely small space.

Stacking the two semiconductor chips in each case with their passive rear sides on each other permits rerouting between them and with respect to the carrier substrate. More specifically, the passive rear sides have first and second stacking areas that are connected to each other in a flat manner.

A further embodiment of the invention provides for the carrier substrate to be provided with an underside facing away from the semiconductor chips and having outer contacts or contact bumps for flip-chip mounting. This permits rapid and cost-effective further processing of the electronic component, which can be placed on a printed circuit board in a straightforward manner and soldered thereto.

A development of the invention provides for the carrier substrate to be configured as a rerouting board. If appropriate, a three-dimensional rerouting structure can also be contained in the carrier substrate, which leads to very compact dimensions of the electronic component according to the invention.

The advantage of an electronic component constructed and produced in accordance with the invention is that a memory module having a rectangular form and a logic module having a square form can be reliably electrically connected to each other in a small space.

A housing that covers the carrier substrate and encloses the semiconductor chips can be configured to be extremely flat and therefore very compact.

A process according to the invention for the production of an electronic component according to one of the embodiments described previously includes providing a first semiconductor chip with first contact areas on a first passive rear side. A second semiconductor chip with second contact areas on a second active chip surface is provided. Also provided is a carrier substrate, which contains a frame and a central recess. Provided on the upper side of the frame are contact connecting areas that are electrically conductively connected to outer contact areas on an underside of the carrier substrate.

The two semiconductor chips are joined to each other in such a way that a first stacking area on the first passive rear side of the first semiconductor chip rests on a second stacking area on a second active chip surface of the second semiconductor chip. The second semiconductor chip is then applied with marginal supporting regions on the upper side of the carrier substrate and fixed by a conductive adhesive layer or a solder layer. Then, first contact areas of the first semiconductor chip are connected to contact connecting areas of the carrier substrate by first bonding wires. Second contact areas of the second semiconductor chip are connected to contact connecting areas of the carrier substrate by second bonding wires. Finally, the electronic component is potted with a housing made of plastic.

The process for the production of the electronic component according to the invention has the advantage that it has very short production times and leads to very compact components.

One exemplary implementation of the process according to the invention provides for additional electrical connections between second contact areas of the second semiconductor chip and third contact areas of the first semiconductor chip to be produced by third bonding wires. These chip-to-chip connections between the first and second semiconductor chip permit a further reduction in the size of the electronic component. The advantage of the exemplary implementation resides in the further increase in the performance of such electronic components, with a considerably reduced space requirement.

As a result of rerouting the first semiconductor chip (for example logic module), it is possible to place the two components one above the other. In order to achieve a low installation height, there is an aperture in the substrate, in which the logic module is located. The chip-on-chip structure is adhesively bonded to the substrate by using the overhangs of the second semiconductor chip (e.g. memory module). Wire bonding is carried out on only two sides of the components. Two-row bonding to the logic module can be carried out. Single-row bonding to the memory module can be carried out (chip to chip or chip to substrate).

There is therefore space for both components in a common housing, which is additionally compact and has a low installation height. By the rerouting of the logic module incorporated countersunk in the substrate, the chips can be placed one above the other. The memory module therefore constitutes a substrate for the logic module and is connected to the actual carrier substrate at its overhangs.

Other features which are considered as characteristic for the invention are set forth in the appended claims.

Although the invention is illustrated and described herein as embodied in an electronic component with at least two stacked semiconductor chips and a process for producing the electronic component, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, plan view of a first semiconductor chip according to the invention;

FIGS. 2A and 2B are diagrammatic, plan views of a second semiconductor chip;

FIG. 3 is a diagrammatic, plan view of an electronic component;

FIG. 4 is a diagrammatic, sectional view of the electronic component shown in FIG. 3; and

FIG. 5 is a detailed, sectional view of the electronic component, rotated through 90° with respect to the illustration of FIG. 4.

### DESCRIPTION OF THE PREFERRED EMBODIMENTS

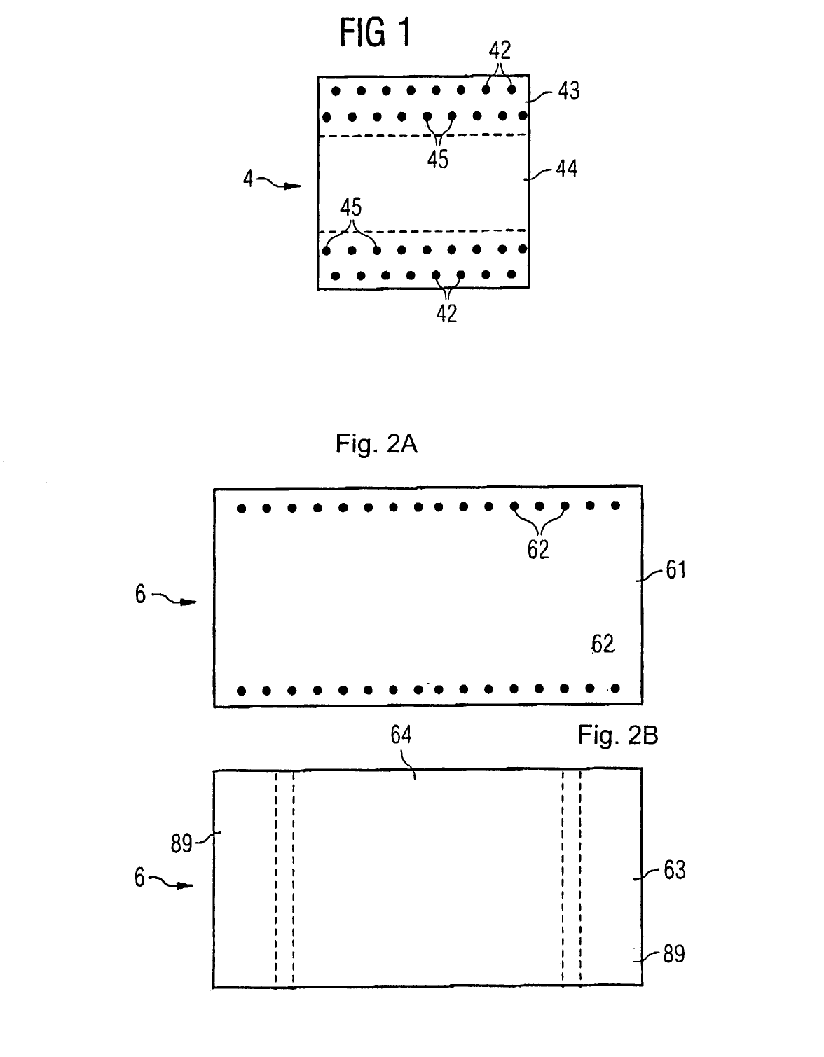

Referring now to the figures of the drawing in detail and first, particularly, to FIG. 1 thereof, there is shown a schematic plan view of a first semiconductor chip 4, which is provided with a plurality of first contact areas 42 and, if appropriate, with a large number of third contact areas 45, on a first passive rear side 43. The first contact areas 42 and the third contact areas 45 are in each case disposed in opposite edge sections of the first passive rear side 43. The contact areas 42, 45 are separated by a first stacking area 44, which reaches from one side edge of the first semiconductor chip 4 without contact areas as far as the opposite side edge. The contact areas 42, 45 are therefore led from a first active chip surface 41 to the first passive rear side 43, for example through vias, as they are known.

FIGS. 2A and 2B shows schematic plan views of a second active chip surface 61 and a second passive rear side 63 (FIG. 2B) of a second semiconductor chip 6. On its second active chip surface 61, the second semiconductor chip 6 is in each case provided with a large number of second contact areas 62, which are in each case located on opposite edge sections of the second active chip surface 61. A second passive rear side 63 of the second semiconductor chip 6 is subdivided into marginal supporting regions 89 and a central second stacking area 64, which divides the supporting regions 89.

In the exemplary embodiment illustrated, the first semiconductor chip 4 has a square contour and can be a logic module, for example. The second semiconductor chip 6 in the exemplary embodiment shown has a rectangular contour and can be a memory module, for example.

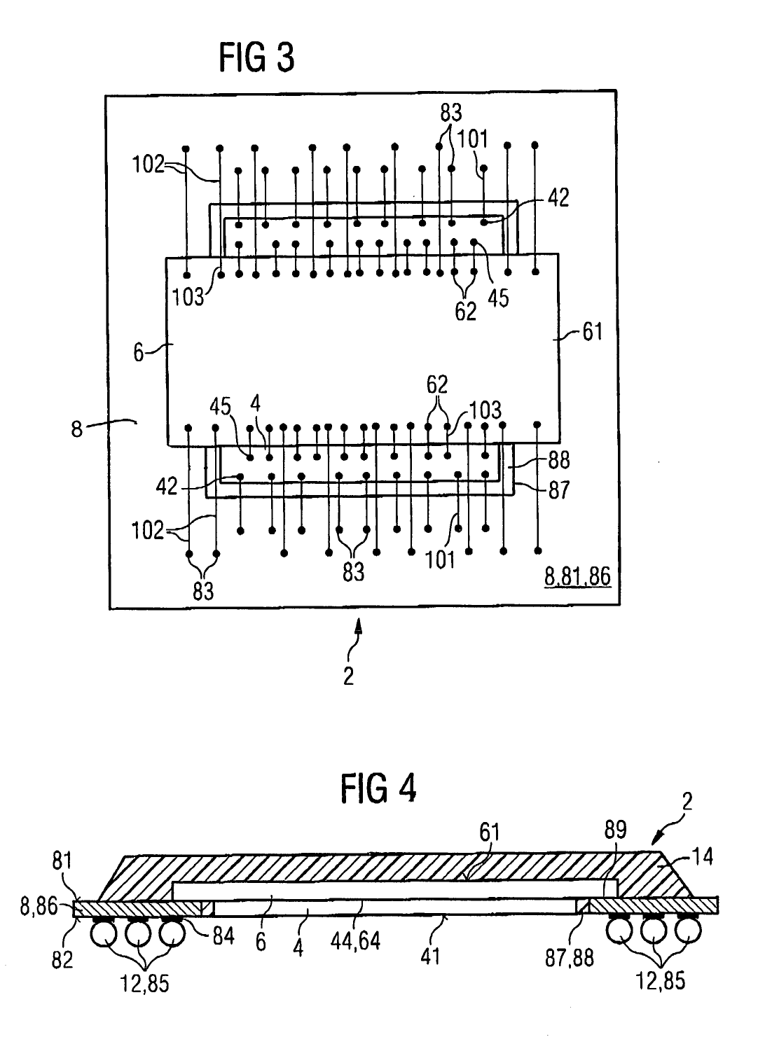

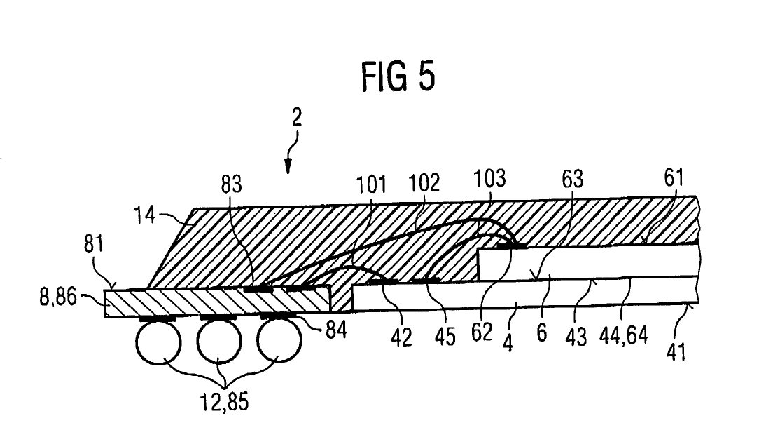

FIG. 3 shows, in a further schematic plan view, an electronic component 2 according to the invention that contains the first semiconductor chip 4, the second semiconductor chip 6 and a carrier substrate 8. The flat carrier substrate 8 has a frame 86 and a central recess 87 disposed substantially centrally therein (also see FIG. 4). The size and dimensions of the substantially square recess 87 are configured such that there is space therein for the first semiconductor chip 4, a circumferential gap 88 remaining between the semiconductor chip 4 and the frame 86.

In the electronic component 2, the first semiconductor chip 4 and second semiconductor chip 6 are joined to each other by their stacking areas 44 and 64. The two joined semiconductor chips 4, 6 are connected to the carrier substrate 8 in such a way that the first semiconductor chip 4 is disposed centrally in the recess 87. For this purpose, the second semiconductor chip 6 is fixed with its supporting regions 89 on the frame 86 of the carrier substrate 8, for example by adhesive bonding or soldering.

In FIG. 3, an upper side 81 of the carrier substrate 8, the first passive rear side 43 of the first semiconductor chip 4 and the second active chip surface 61 of the second semiconductor chip 6 point toward the observer. It therefore becomes clear that the first passive rear side of the first semiconductor chip 4 is connected to the second passive rear side 63 of the second semiconductor chip 6.

In FIG. 3, electrical connections from the first semiconductor chip 4 to the carrier substrate 8 and from the second semiconductor chip 6 to the carrier substrate 8 can also be seen. The electrical connections are produced by first bonding wires 101 and by second bonding wires 102. In this case, the first bonding wires 101 lead from first contact areas 42 of the first semiconductor chip 4 to contact connecting areas 83 on the carrier substrate 8. Furthermore, second bonding wires 102 lead from the second contact areas 62 of the second semiconductor chip 6 to the contact connecting areas 83 of the carrier substrate 8.

In the exemplary embodiment, third bonding wires 103 are also shown, which lead from the second contact areas 62 of the second semiconductor chip 6 to the third contact areas 45 of the first semiconductor chip 4. The third bonding wires 103 therefore constitute chip-to-chip connections, as they are known, between the first and second semiconductor chip 4, 6. The third bonding wires 103 are optional. Embodiments of the invention are also conceivable in which no direct electrical connections are provided between the two semiconductor chips 4, 6.

FIG. 4 shows a schematic sectional view of the electronic component 2 in a direction in which the bonding wires 101, 102, 103 are oriented at right angles to the plane of the drawing and are therefore not visible. It is possible to see the first and second semiconductor chips 4, 6 resting on each other with the first stacking area 44 and second stacking area 64. It is possible to see the second semiconductor chip 6 resting with its supporting regions 89 on the frame 86 of the carrier substrate 8. It is also possible to see the first semiconductor chip 4 which is located in the recess 87 and which is therefore located on one plane with the carrier substrate 8.

The carrier substrate 8, which may possibly be a routing board made of ceramic, epoxy material or polyimide, for example, is provided with contact areas 84 on an underside 82 opposite the upper side 81, the contact areas 84 each being provided with outer contacts 85 (illustrated here as contact bumps 12). The two semiconductor chips 4, 6 and the upper side 81 of the carrier substrate 8 are covered by a housing 14, which additionally fills the gap 88 between the frame 86 and the first semiconductor chip 4. The housing 14 is, for example, a plastic housing 14, which can be produced by transfer molding or by an injection molding technique.

Finally, FIG. 5 shows a detailed section of the electronic component 2 in a section plane rotated through 90° with respect to the illustration of FIG. 4. In this case, it is possible to see clearly the electrical connections between the first semiconductor chip 4 and the carrier substrate 8 and between the second semiconductor chip 6 and the carrier substrate 8. It is also possible to see the optional chip-to-chip connections between the first and second semiconductor chips 4, 6. In this case, the first bonding connections (first bonding wires 101) lead from the first contact areas 42 on the first passive rear side 43 of the first semiconductor chip 4 to the contact connecting areas 83 on the upper side 81 of the carrier substrate 8.

Furthermore, it is possible to see the second bonding wire 102, which leads from the second contact area 62 to a further one of the contact connecting areas 83. If necessary, the third bonding wires 103 can be provided, which lead from the second contact areas 62 to the third contact areas 45 on the passive rear side 43 of the first semiconductor chip 4. In this view, it is also possible to see the housing 14 of plastic that fills the gap 88.

In the following text, a process according to the invention for the production of the electronic component 2 will be explained by using FIGS. 1 to 5. For this purpose, first the first semiconductor chip 4 (see FIG. 1) and the second semiconductor chip 6 (see FIG. 2) are provided. The two semiconductor chips 4, 6 are joined to each other, the first stacking area 44 on the first passive rear side 43 of the first semiconductor chip 4 resting on the second stacking area 64 on the second active chip surface 61 of the second semiconductor chip 6.

The second semiconductor chip 6 is then applied with its marginal supporting regions 89 on the upper side 81 of the carrier substrate 8 and fixed by a conductive adhesive layer or a solder layer. Then, the first contact areas 42 of the first semiconductor chip 4 are connected to the contact connecting areas 83 of the carrier substrate 8 by the first bonding wires 101. This is followed by the connection of the second contact areas 62 of the second semiconductor chip 6 to the contact connecting areas 83 of the carrier substrate 8 by the second bonding wires 102, after which, finally, the electronic component 2 is potted in the housing 14. The embodiment illustrated in FIGS. 3 to 5 additionally provides additional electrical connections between the second semiconductor chip 6 and the first semiconductor chip 4. The additional electrical connections between the second contact areas 62 of the second semiconductor chip 6 and the third contact areas 43 of the first semiconductor chip 4 are produced by the third bonding wires 103, by that a chip-to-chip connection, as it is known, is achieved.

By the configuration and construction according to the invention of the semiconductor chips 4, 6, the electronic component 2 having an extremely compact configuration is provided which, because of contact being made between the first and the second semiconductor chips 4, 6 and the carrier substrate 8, has short signal paths, which ensure optimum switching and control performance of the electronic component 2.

We claim:

1. An electronic component, comprising:
semiconductor chips including a first semiconductor chip and a second semiconductor chip; and
a carrier substrate accommodating said semiconductor chips and having an upper side and a frame with a central recess formed therein, said second semiconductor chip having two opposite marginal supporting regions resting on said upper side of said carrier substrate, said first semiconductor chip connected to said second semiconductor chip and disposed at a distance from said frame in said central recess of said carrier substrate.

2. The electronic component according to claim 1, further comprising:
first bonding wires electrically conductively connecting said first semiconductor chip to said upper side of said carrier substrate; and
second bonding wires electrically conductively connecting said second semiconductor chip to said upper side of said carrier substrate.

3. The electronic component according to claim 2, further comprising third bonding wires electrically connecting said first semiconductor chip to said second semiconductor chip.

4. The electronic component according to claim 1, wherein said first and second semiconductor chips each has a passive rear side and are stacked on each other on said passive rear sides.

5. The electronic component according to claim 4, wherein:
said passive rear side of said first semiconductor chip has a first stacking area; and
said passive rear side of said second semiconductor chip has a second stacking area, said first stacking area connected in a flat manner to said second stacking area.

6. The electronic component according to claim 1,
wherein said carrier substrate has an underside facing away from said semiconductor chips; and
further comprising one of outer contacts and contact bumps for flip-chip mounting disposed on said underside of said carrier substrate.

7. The electronic component according to claim 1, wherein said carrier substrate is a rerouting board.

8. The electronic component according to claim 1, wherein said first semiconductor chip has a square form and is a logic module.

9. The electronic component according to claim 1, wherein said second semiconductor chip has a rectangular form and is a memory module.

10. The electronic component according to claim 1, further comprising a housing accommodating said first and second semiconductor chips.

11. A process for producing an electronic component, which comprises the steps of:
providing a first semiconductor chip having a passive rear side with a first stacking area and first contact areas disposed on the passive rear side;
providing a second semiconductor chip having marginal supporting regions, an active chip surface with a second stacking area, and second contact areas disposed on the active chip surface;
providing a flat carrier substrate having a frame with a central recess formed therein, an upper side, and contact connecting areas disposed on the upper side;
joining the first semiconductor chip to the second semiconductor chip such that the first stacking area of the first semiconductor chip rests on the second stacking area of the second semiconductor chip;
fixing the marginal supporting regions of the second semiconductor chip on the upper side of the carrier substrate using one of a conductive adhesive layer and a solder layer;
using first bonding wires to connect the first contact areas of the first semiconductor chip to the contact connecting areas of the carrier substrate;
using second bonding wires to connect the second contact areas of the second semiconductor chip to further ones of the contact connecting areas of the carrier substrate; and
potting the semiconductor chips and the carrier substrate in a housing.

12. The process according to claim 11, which comprises using third bonding wires to form electrical connections between the second contact areas of the second semiconductor chip and third contact areas of the first semiconductor chip.
